(19) United States
(12) Patent Application Publication
(10) Pub. No.: US 2026/0143780 A1
(43) Pub. Date: May 21, 2026

(54) SEMICONDUCTOR DEVICE AND SEMICONDUCTOR DEVICE MANUFACTURING METHOD

(71) Applicant: Samsung Electronics Co., Ltd., Suwon-si (KR)

(72) Inventors: Eunji YANG, Suwon-si (KR); Baekwon PARK, Suwon-si (KR); Changhyun KIM, Suwon-si (KR)

(73) Assignee: Samsung Electronics Co., Ltd., Suwon-si (KR)

(21) Appl. No.: 19/389,912

(22) Filed: Nov. 14, 2025

(30) Foreign Application Priority Data
Nov. 15, 2024 (KR) 10-2024-0163346

(51) Int. Cl. H10D 64/27; H10D 30/01; H10D 30/47

(52) U.S. Cl. CPC H10D 64/519; H10D 30/017; H10D 30/481

(57) ABSTRACT

A semiconductor device may include a plurality of gate bridges, a gate via connecting the plurality of gate bridges to each other, a channel layer between the plurality of gate bridges, and a source electrode apart from the gate via in a first direction. The plurality of gate bridges may pass through a portion of the source electrode.

### CROSS-REFERENCE TO RELATED APPLICATION

This application is based on and claims priority under 35 U.S.C. § 119 to Korean Patent Application No. 10-2024-0163346, filed on Nov. 15, 2024, in the Korean Intellectual Property Office, the disclosure of which is incorporated by reference herein in its entirety.

### BACKGROUND

### 1. Field

The disclosure relates to a semiconductor device and/or a semiconductor device manufacturing method.

### 2. Description of the Related Art

As a semiconductor process becomes more refined, a transistor size decreases and the area in which a gate electrode and a channel contact each other decreases, thus causing issues due to a short channel effect. In order to reduce the short channel effect and/or improve gate control, a gate-all-around (GAA) structure has attracted attention. A transition metal dichalcogenide (TMD) material has sufficient or excellent scaling characteristics and thus may be advantageous for implementing a multi-bridge channel FET (MBCFET) with a GAA structure.

However, there may be several process issues that make it more difficult to directly apply an existing silicon-based process to a TMD material. Thus, it may be advantageous to develop a TMD MBCFET manufacturing process that limits and/or minimizes damage to the TMD during the process.

### SUMMARY

Provided are a semiconductor device with a gate-all-around (GAA) structure and/or a method of manufacturing the semiconductor device.

Additional aspects will be set forth in part in the description which follows and, in part, will be apparent from the description, or may be learned by practice of the presented embodiments of the disclosure.

According to an example embodiment of the disclosure, a semiconductor device may include a plurality of gate bridges extending in a first direction and apart from each other in a second direction, the second direction being different from the first direction; a gate via extending in the second direction and connecting the plurality of gate bridges to each other; a channel layer between the plurality of gate bridges; and a source electrode extending in the second direction and apart from the gate via in the first direction. The plurality of gate bridges may pass through a portion of the source electrode.

In some embodiments, the plurality of gate bridges may include titanium nitride (TiN).

In some embodiments, the semiconductor device may further include a drain electrode extending in the second direction. The drain electrode may be apart from the source electrode in the first direction.

In some embodiments, the semiconductor device may further include a spacer between the drain electrode and at least one of the plurality of gate bridges.

In some embodiments, the channel layer may include a transition metal dichalcogenide (TMD).

In some embodiments, the TMD may include MoS₂, WSe₂, MoSe₂, or WS₂.

In some embodiments, the semiconductor device may further include a gate insulating layer surrounding at least one of the plurality of gate bridges.

In some embodiments, at least a portion of the gate insulating layer may include a portion with a U-shaped cross-section, and the source electrode may overlap the portion with the U-shaped cross-section of the gate insulating layer. The source electrode may fill the portion with the U-shaped cross-section of the gate insulating layer.

In some embodiments, the gate insulating layer may include a high-k material.

In some embodiments, the gate insulating layer may include at least one of aluminum oxide, hafnium oxide, zirconium oxide, or lanthanum oxide.

In some embodiments, the gate via may include TiN.

According to an example embodiment of the disclosure, a semiconductor device may include a plurality of gate bridges extending in a first direction and apart from each other in a second direction, the second direction being different from the first direction; a gate via extending in the second direction and connecting the plurality of gate bridges to each other; a channel layer between the plurality of gate bridges; a source electrode extending in the second direction and apart from the gate via in the first direction; and a drain electrode extending in the second direction and apart from the source electrode in the first direction. The gate via, the source electrode, and the drain electrode may be arranged in the first direction.

In some embodiments, at least one of the plurality of gate bridges may pass through a portion of the source electrode.

In some embodiments, the semiconductor device may further include a gate insulating layer surrounding at least one of the plurality of gate bridges.

In some embodiments, the semiconductor device may further include a spacer between the drain electrode and at least one of the plurality of gate bridges.

In some embodiments, the channel layer may include a transition metal dichalcogenide (TMD).

In some embodiments, the TMD may include MoS₂, WSe₂, MoSe₂, or WS₂.

According to an example embodiment of the disclosure, a semiconductor device manufacturing method may include forming a plurality of gate bridges extending in a first direction on a substrate, the plurality of gate bridges being apart from each other in a second direction away from the substrate, the second direction being different from the first direction; forming a gate via extending in the second direction and connecting the plurality of gate bridges to each other; forming a gate insulating layer covering the plurality of gate bridges; forming a source electrode extending in the second direction and apart from the gate via in the first direction; and forming a channel layer between the plurality of gate bridges. The plurality of gate bridges may pass through a portion of the source electrode.

In some embodiments, the semiconductor device manufacturing method may further include forming a drain electrode, where the drain electrode may extend in the second direction and may be apart from the source electrode in the first direction.

In some embodiments, the semiconductor device manufacturing method may further include forming a spacer between the drain electrode and at least one of the plurality of gate bridges.

In some embodiments, the channel layer may include a transition metal dichalcogenide (TMD).

In some embodiments, the TMD may include MoS₂, WSe₂, MoSe₂, or WS₂.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view illustrating a semiconductor device according to an embodiment;

FIG. 2A is a cross-sectional view taken along line A-A′ of FIG. 1;

FIG. 2B is a cross-sectional view taken along line B-B′ of FIG. 1;

FIG. 2C is a cross-sectional view taken along line C-C′ of FIG. 1;

FIG. 3A is a modification of the cross-sectional view taken along line A-A′ of FIG. 1;

FIG. 3B is a modification of the cross-sectional view taken along line B-B′ of FIG. 1;

FIG. 4 is a cross-sectional view taken along line A-A′ of FIG. 1;

FIGS. 5A to 5L are diagrams describing a semiconductor device manufacturing method according to an embodiment;

FIGS. 6A and 6B are diagrams describing a portion of a semiconductor device manufacturing method according to an embodiment;

FIG. 7 is a schematic block diagram of a display driver IC (DDI) including a field-effect transistor and a display apparatus including the DDI, according to an embodiment;

FIG. 8 is a block diagram of an electronic system including a semiconductor device according to an embodiment; and

FIG. 9 is a block diagram of an electronic system including a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

Hereinafter, semiconductor devices and semiconductor device manufacturing methods according to various embodiments will be described in detail with reference to the accompanying drawings. Like reference numerals in the drawings will denote like elements, and sizes of elements in the drawings may be exaggerated for clarity and convenience of description. Also, the embodiments described below are merely examples, and various modifications may be made therein.

As used herein, the terms “over” or “on” may include not only “directly over” or “directly on” but also “indirectly over” or “indirectly on”. As used herein, the singular forms “a”, “an”, and “the” are intended to include the plural forms as well, unless the context clearly indicates otherwise. Also, when something is referred to as “including” a component, another component may be further included unless specified otherwise.

The use of the terms “a”, “an”, and “the” and other similar indicative terms may be construed to cover both the singular and the plural. Unless there is an explicit order or a contrary description, operations constituting a method may be performed in a suitable order and are not necessarily limited to the described order.

Connections or connection members of lines between the elements illustrated in the drawings may illustratively represent functional connections and/or physical or logical connections and may be represented as various replaceable or additional functional connections, physical connections, or logical connections in an actual apparatus.

All examples or illustrative terms used herein are merely intended to describe technical concepts of the disclosure in detail, and the scope of the disclosure is not limited by these examples or illustrative terms unless otherwise defined in the appended claims.

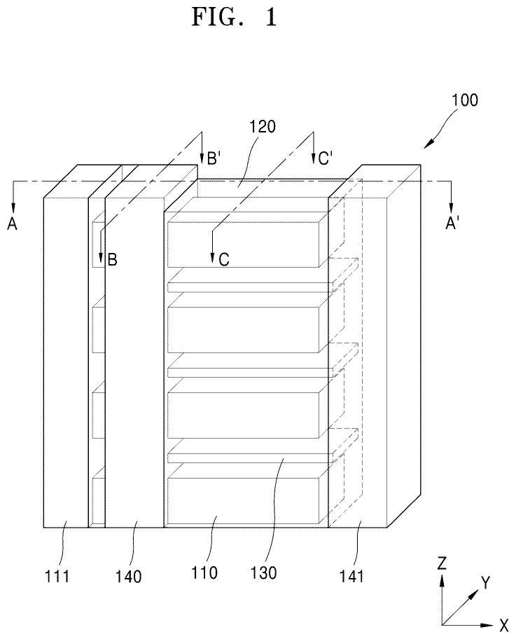

FIG. 1 is a perspective view illustrating a semiconductor device according to an embodiment.

Referring to FIG. 1, a semiconductor device 100 may include a plurality of gate bridges 110 extending in a first direction (x direction) and apart from each other in a second direction (z direction) that is different from the first direction (x direction), a gate via 111 extending in the second direction (z direction) and connected to the plurality of gate bridges 110, a channel layer 130 arranged between the plurality of gate bridges 110, a source electrode 140 extending in the second direction (z direction) and to be apart from the gate via 111 in the first direction (x direction), and a drain electrode 141 extending in the second direction (z direction) and apart from the source electrode 140 in the first direction (x direction).

FIG. 1 illustrates that four gate bridges 110 are arranged; however, the disclosure is not limited thereto and two or more gate bridges may be arranged.

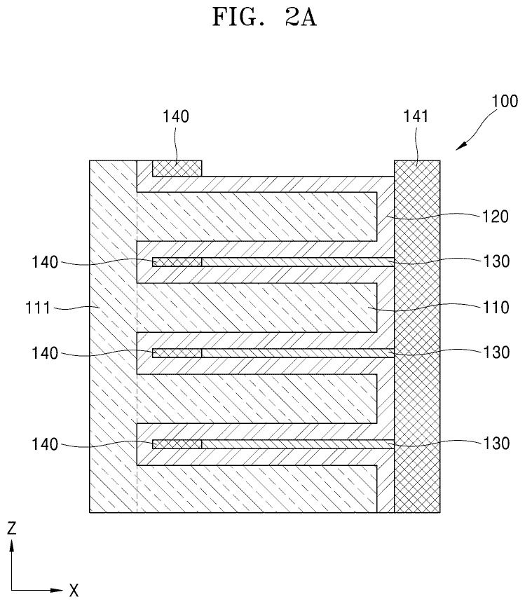

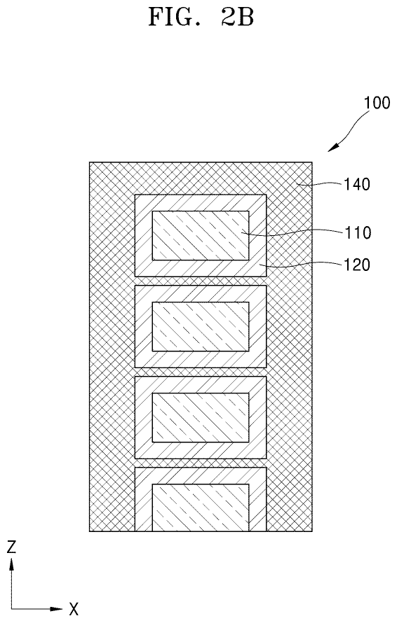

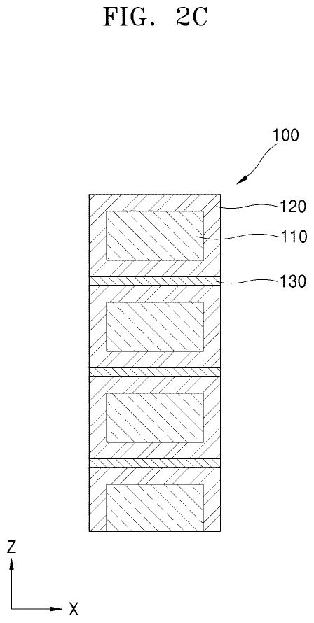

FIG. 2A is a cross-sectional view taken along line A-A′ of FIG. 1, FIG. 2B is a cross-sectional view taken along line B-B′ of FIG. 1, and FIG. 2C is a cross-sectional view taken along line C-C′ of FIG. 1.

Referring to FIGS. 2A to 2C, the semiconductor device 100 may include a gate insulating layer 120 arranged to be surrounded by a source electrode 140, a gate bridge 110 arranged to be surrounded by a gate insulating layer 120, a gate via 111 arranged to connect gate bridges 110 to each other, and a channel layer 130 arranged between gate insulating layers 120.

A plurality of gate bridges 110 may be arranged to pass through a portion of the source electrode 140. At least one of the plurality of gate bridges 110 may overlap the source electrode 140 in the second direction (z direction) in a partial area. As the gate bridge 110 overlaps the source electrode 140 in the second direction (z direction), the source electrode 140 may be electrically doped. As the gate bridge 110 overlaps the source electrode 140 in the second direction (z direction), when a voltage is applied to the gate bridge 110, a voltage may also be applied to the source electrode 140 and the source electrode 140 may be electrically doped.

The gate via 111 may be connected to one end of the plurality of gate bridges 110 to connect the plurality of gate bridges 110 to each other.

The plurality of gate bridges 110 may include a metal material or a conductive oxide. The metal material may include, for example, at least one selected from among Au, Ti, TiN, TaN, W, Mo, WN, Pt, and Ni. The conductive oxide may include, for example, indium tin oxide (ITO) or indium zinc oxide (IZO).

The gate via 111 may include the same material as the plurality of gate bridges 110. The gate via 111 may include a metal material or a conductive oxide. The metal material may include, for example, at least one selected from among Au, Ti, TiN, TaN, W, Mo, WN, Pt, and Ni. The conductive oxide may include, for example, indium tin oxide (ITO) or indium zinc oxide (IZO).

The channel layer 130 may be formed between the gate insulating layers 120.

The channel layer 130 may be apart from each gate bridge 110 and may be between the plurality of gate bridges 110.

The channel layer 130 may be formed between two adjacent gate bridges among the plurality of gate bridges 110. The channel layer 130 may be between the plurality of gate bridges 110 and thus the semiconductor device 100 may have a dual-gate structure. The space between the channel layer 130 and the plurality of gate bridges 110 may be filled with the gate insulating layer 120.

The channel layer 130 may be between the source electrode 140 and the drain electrode 141 and thus may function as a path through which a current flows between the source electrode 140 and the drain electrode 141. The channel layer 130 may directly contact the source electrode 140 and the drain electrode 141. However, the channel layer 130 is not limited thereto, and the channel layer 130 may also be connected to the source electrode 140 and the drain electrode 141 through another medium.

The channel layer 130 may include, for example, a transition metal dichalcogenide (TMD). The TMD may be represented as, for example, MX₂, where M denotes a transition metal and X denotes a chalcogen element. For example, M may be Mo, W, Nb, V, Ta, Ti, Zr, Hf, Tc, Re, or the like, and X may be S, Se, Te, or the like. Thus, the TMD may include MoS₂, WSe₂, MoSe₂, or WS₂. However, the materials mentioned above are merely examples, and other materials may be used as the TMD material.

The channel layer 130 may be provided as a plurality of channel layers 130. The plurality of channel layers 130 may extend in the first direction (x direction) and to be apart from each other in the second direction (z direction). The plurality of gate bridges 110 and the plurality of channel layers 130 may be alternately arranged. The channel layer 130 may be arranged not to overlap the source electrode 140 in the second direction (z direction).

However, in some embodiments due to the process limitation, the channel layer 130 may partially overlap the source electrode 140 in the second direction (z direction).

The gate insulating layer 120 may surround at least one of the plurality of gate bridges 110. The gate insulating layer 120 may be arranged to surround at least one of the plurality of channel layers 130. The gate insulating layer 120 may insulate the gate bridges 110 and the channel layers 130 from each other and may limit and/or suppress a leakage current.

The source electrode 140 may be arranged to fill a portion with a U-shaped cross-section of the gate insulating layer 120. Because the source electrode 140 may be arranged to fill a portion with a U-shaped cross-section of the gate insulating layer 120, the channel layer 130 may not fill the portion with a U-shaped cross-section of the gate insulating layer 120.

The gate insulating layer 120 may include a high-k (high-dielectric) material. The gate insulating layer 120 may include, for example, aluminum oxide, hafnium oxide, zirconium oxide, zirconium hafnium oxide, or lanthanum oxide. However, the disclosure is not limited thereto.

The gate insulating layer 120 may include a ferroelectric material. The ferroelectric material may have a non-centrosymmetric charge distribution in a unit cell in a crystallized material structure and thus may have a spontaneous electric dipole, that is, a spontaneous polarization. Thus, the ferroelectric material may have a remnant polarization due to a dipole even in the absence of an external electric field. Also, the direction of the polarization may be switched in units of domains by an external electric field. The ferroelectric material may include, for example, an oxide of at least one selected from among Hf, Si, Al, Zr, Y, La, Gd, and Sr; however, this is merely an example. Also, when necessary, the ferroelectric material may further include a dopant.

When the gate insulating layer 120 includes a ferroelectric material, the semiconductor device 100 may be applied, for example, as a logic device or a memory device. When the gate insulating layer 120 includes a ferroelectric material, because a subthreshold swing (SS) may be reduced by a negative capacitance effect, the performance of the semiconductor device 100 may be improved while reducing the size of the semiconductor device 100.

The gate insulating layer 120 may have a multilayer structure including a high-k material and a ferroelectric material. Because the gate insulating layer 120 may include a charge trapping material such as silicon nitride, the semiconductor device 100 may operate as a memory transistor having memory characteristics.

The drain electrode 141 may be arranged not to overlap the gate bridge 110 in the second direction (z direction). As the drain electrode 141 may not overlap the gate bridge 110 in the second direction (z direction), the drain electrode 141 may not be electrically doped. As the drain electrode 141 may not be electrically doped, a leakage current may be limited and/or minimized.

The source electrode 140 and the drain electrode 141 may include a metal material having electrical conductivity. For example, the source electrode 140 and the drain electrode 141 may include a metal, such as magnesium (Mg), aluminum (Al), scandium (Sc), titanium (Ti), vanadium (V), chromium (Cr), manganese (Mn), nickel (Ni), copper (Cu), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), and bismuth (Bi), or any alloy thereof.

The gate via 111, the source electrode 140, and the drain electrode 141 may be arranged to overlap each other in any one direction. The gate via 111, the source electrode 140, and the drain electrode 141 may be arranged to overlap each other, for example, in the first direction (x direction).

In the semiconductor device 100 according to an embodiment, as the source electrode 140 overlaps the gate bridge 110 in the second direction (z direction) and the drain electrode 141 does not overlap the gate bridge 110 in the second direction (z direction), the source electrode 140 may be electrically doped and the drain electrode 140 may not be electrically doped. Accordingly, the leakage current may be reduced and the device characteristics may be improved.

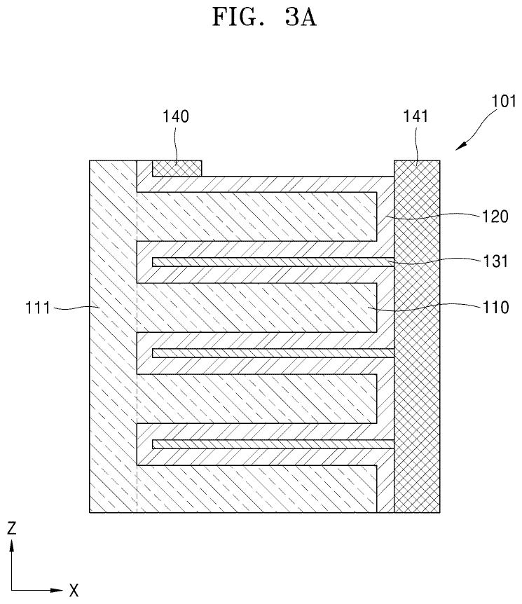

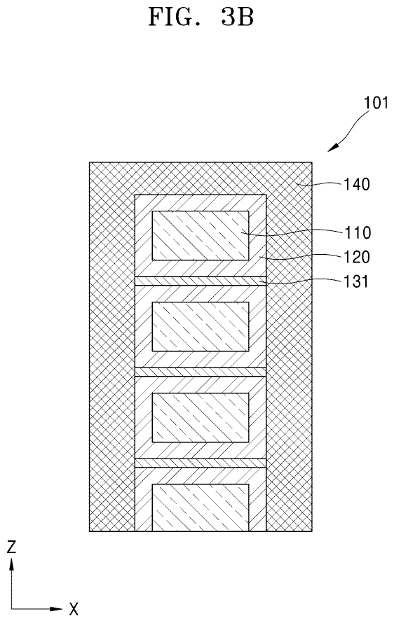

FIG. 3A is a modification of the cross-sectional view taken along line A-A′ of FIG. 1, and FIG. 3B is a modification of the cross-sectional view taken along line B-B′ of FIG. 1.

Referring to FIGS. 3A and 3B, a semiconductor device 101 may include a plurality of gate bridges 110 arranged to be surrounded by a gate insulating layer 120, a gate via 111 arranged to connect the plurality of gate bridges 110 to each other, and a channel layer 131 arranged between gate insulating layers 120.

The channel layer 131 may be arranged to extend in the first direction (x direction).

At least a portion of the gate insulating layer 120 may include a portion with a U-shaped cross-section. The channel layer 131 may be arranged to entirely fill a space defined by the U shape of the gate insulating layer 120. The channel layer 131 may be arranged to overlap the source electrode 140 in the second direction (z direction). Except that the channel layer 131 may be arranged to overlap the source electrode 140 in the second direction (z direction), the semiconductor device 101 may be the same as the semiconductor device 100 described above with reference to FIGS. 2A to 2C.

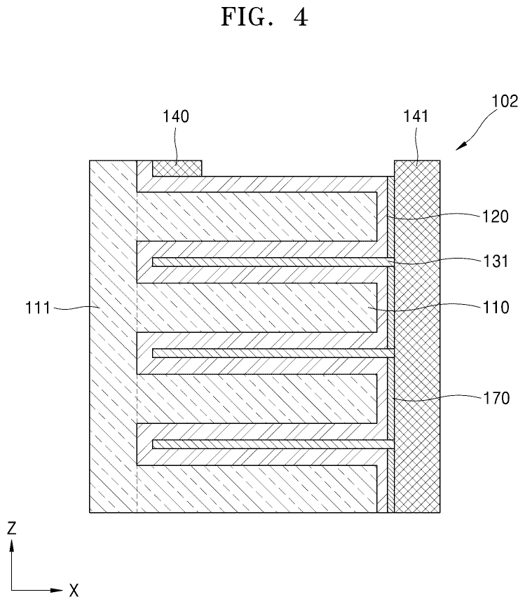

FIG. 4 is a modification of the cross-sectional view taken along line A-A′ of FIG. 1.

Referring to FIG. 4, a semiconductor device 102 may include a plurality of gate bridges 110 arranged to be surrounded by a gate insulating layer 120, a gate via 111 arranged to connect the plurality of gate bridges 110 to each other, a channel layer 131 arranged between gate insulating layers 120, a drain electrode 141 arranged apart from a source electrode 140 in the first direction (x direction), and a spacer 170 arranged between the drain electrode 141 and at least one of the plurality of gate bridges 110.

The spacer 170 may be arranged to insulate the drain electrode 141 and the gate bridge 110 from each other. The insulation may be achieved by the gate insulating layer 120, but the spacer 170 may be further arranged to supplement the insulation of the gate insulating layer 120.

The spacer 170 may include an insulating material. The spacer 170 may include a low-k (low-dielectric) material. The spacer 170 may include, for example, SiO₂ or Si₃N₄.

Except that the spacer 170 may be arranged between the drain electrode 141 and the plurality of gate bridges 110, the semiconductor device 102 may be the same as the semiconductor device 101 described above with reference to FIGS. 3A and 3B.

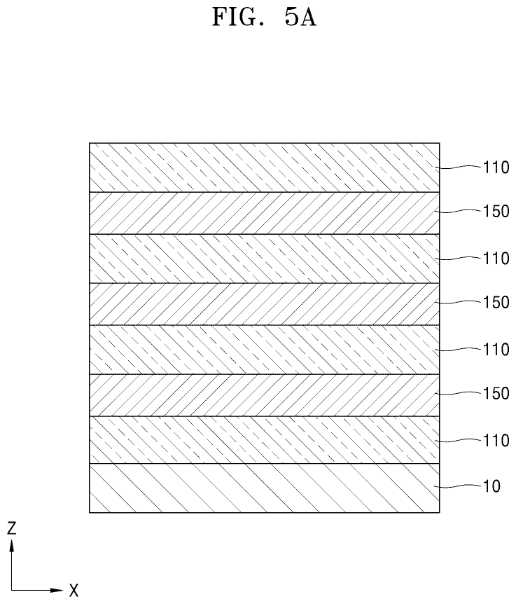

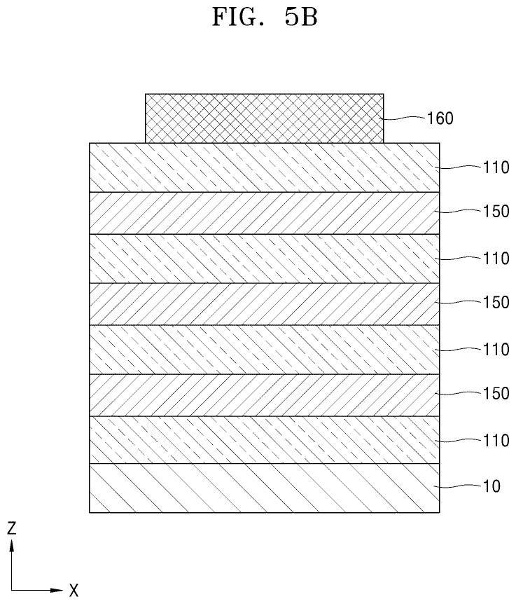

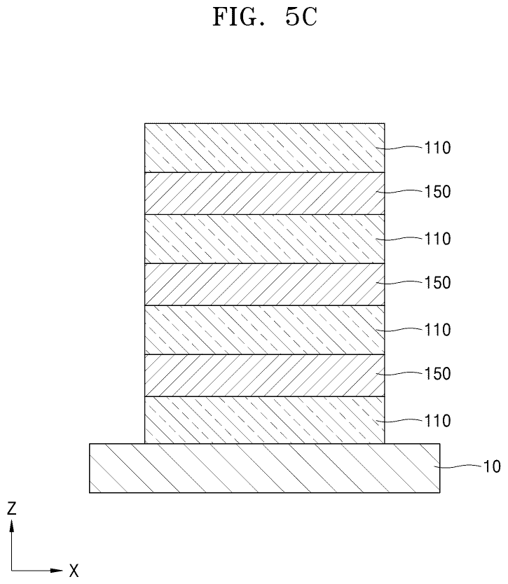

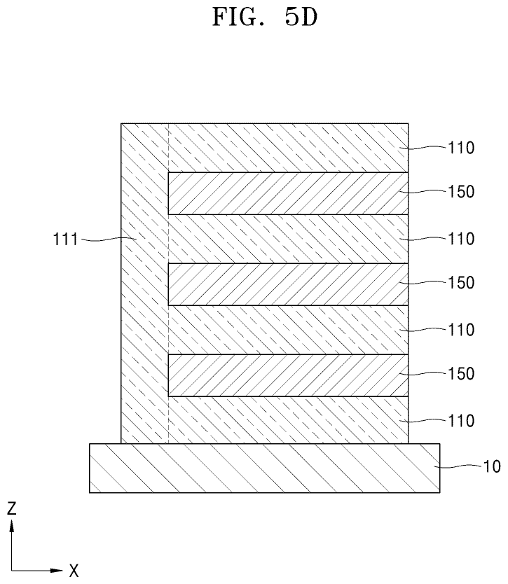

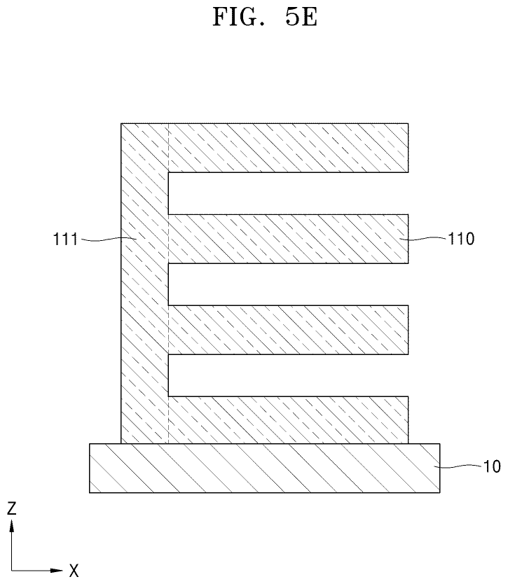

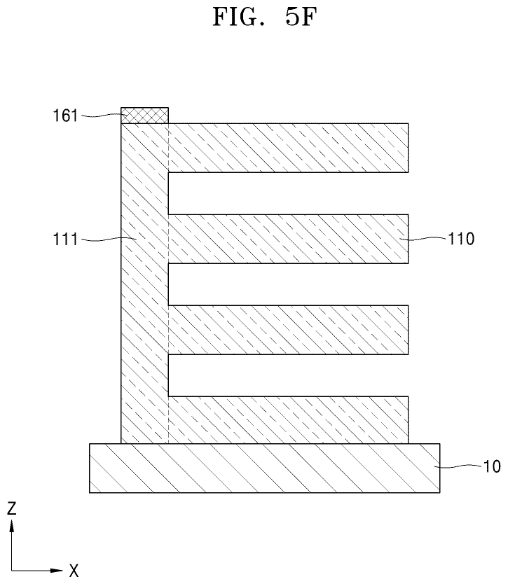

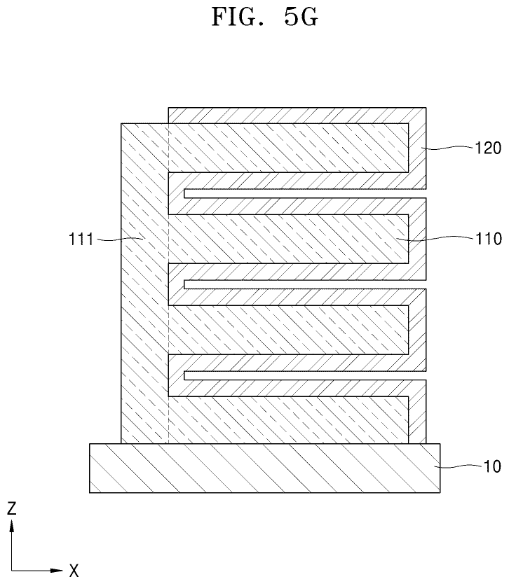

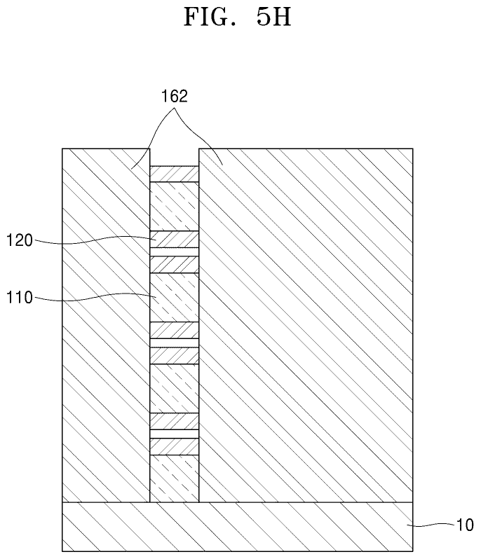

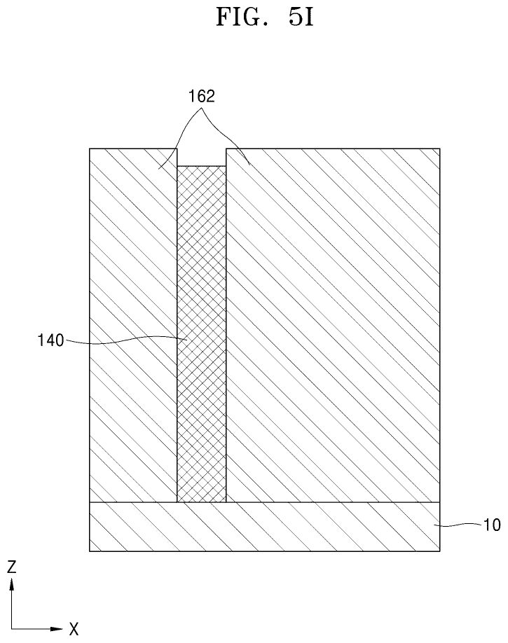

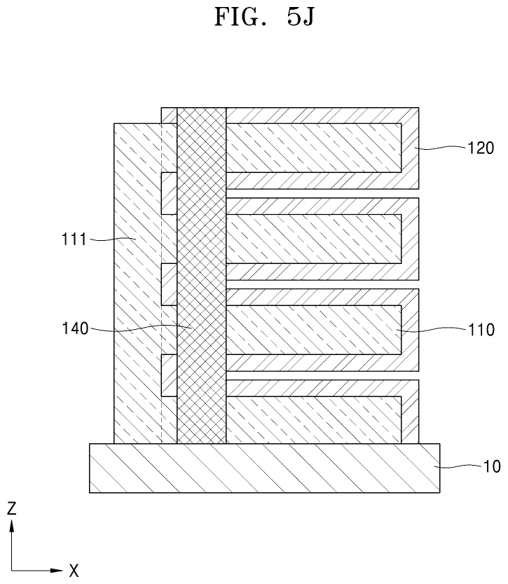

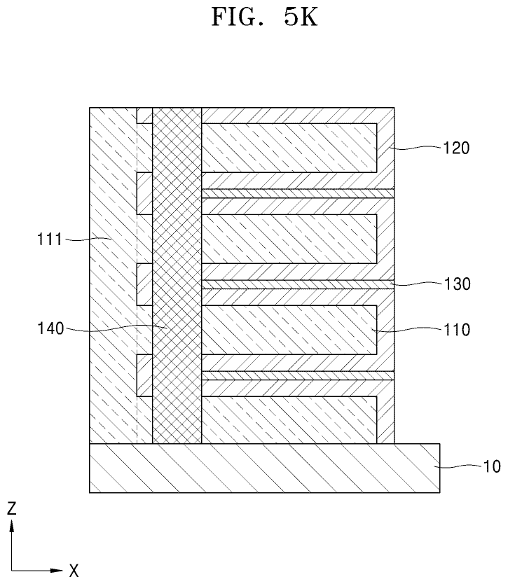

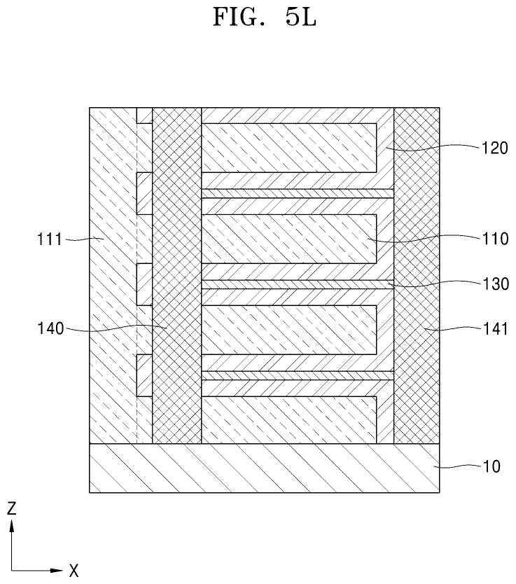

FIGS. 5A to 5L are diagrams describing a semiconductor device manufacturing method according to an embodiment.

Referring to FIG. 5A, sacrificial layers 150 and gate bridges 110 may be alternately stacked over a substrate 10 in the second direction (z direction) away from the substrate 10 to form a stack structure. The substrate 10 may be an insulating substrate or may be a semiconductor substrate with an insulating layer formed on a surface thereof. The substrate 10 may include, for example, silicon (Si) such as monocrystalline silicon, polycrystalline silicon, or amorphous silicon. The substrate 10 may include a group IV semiconductor such as germanium (Ge), a group IV-IV compound semiconductor such as silicon germanium (SiGe) or silicon carbide (SiC), or a group III-V compound semiconductor such as gallium arsenide (GaAs), indium arsenide (InAs), or indium phosphide (InP). The substrate 10 may be based on a silicon bulk substrate or may be based on a silicon-on-insulator (SOI) substrate. The substrate 10 is not limited to a bulk or SOI substrate and may be a substrate based on an epitaxial wafer, a polished wafer, an annealed wafer, or the like. The substrate 10 may include a conductive area, for example, a doped well or various doped structures. Also, the substrate 10 may be configured as a p-type substrate or an n-type substrate depending on the type of dopant ions.

The sacrificial layer 150 and the gate bridge 110 may include materials that may be selectively removed depending on an etching gas or an etching solution. The sacrificial layer 150 may include, for example, an inorganic material such as SiO₂, Al₂O₃, Si₃N₄, poly-Si, or SiGe or an organic material such as polymethyl methacrylate (PMMA).

The gate bridges 110 may extend in the first direction (x direction) and may be apart from each other in the second direction (z direction), where the second direction may be different from the first direction (x direction) and may be away from the substrate 10. The gate bridge 110 may include, for example, titanium nitride (TiN).

Referring to FIGS. 5B and 5C, a photoresist (PR) 160 may be arranged on the top of a stack structure of the sacrificial layers 150 and the gate bridges 110, and then, both side areas of the stack structure may be etched to pattern the stack structure.

Referring to FIG. 5D, a gate via 111 may be formed on the side surface of the stack structure of the sacrificial layers 150 and the gate bridges 110. The gate via 111 may be arranged to extend in the second direction (z direction) and to connect a plurality of gate bridges 110 to each other.

Referring to FIGS. 5E and 5F, the sacrificial layer 150 may be removed, and then, a PR 161 may be formed on the gate via 111. As the sacrificial layer 150 is removed, the plurality of gate bridges 110 may be arranged apart from each other in the second direction (z direction) away from the substrate 10.

Referring to FIG. 5G, a gate insulating layer 120 may be formed to cover each of the plurality of gate bridges 110. The gate insulating layer 120 may be formed, for example, by using atomic layer deposition (ALD).

Referring to FIGS. 5H to 5J, a PR 162 may be patterned in an area other than an area in which a source electrode 140 is to be formed, and then, a source electrode 140 arranged to extend in the second direction (z direction) and to be apart from the gate via 111 in the first direction (x direction) may be formed. The source electrode 140 may include, for example, a metal material having excellent electrical conductivity, such as Ag, Au, Pt, or Cu; however, the disclosure is not limited thereto. After the source electrode 140 is formed, the PR 162 may be removed.

Referring to FIG. 5K, a plurality of channel layers 130 may be formed between the plurality of gate bridges 110. The channel layer 130 may be formed by a chemical vapor deposition (CVD) process, a metal organic chemical vapor deposition (MOCVD) process, or an ALD process.

Referring to FIG. 5L, a drain electrode 141 may be formed. The drain electrode 141 may include, for example, a metal material having excellent electrical conductivity, such as Ag, Au, Pt, or Cu; however, the disclosure is not limited thereto.

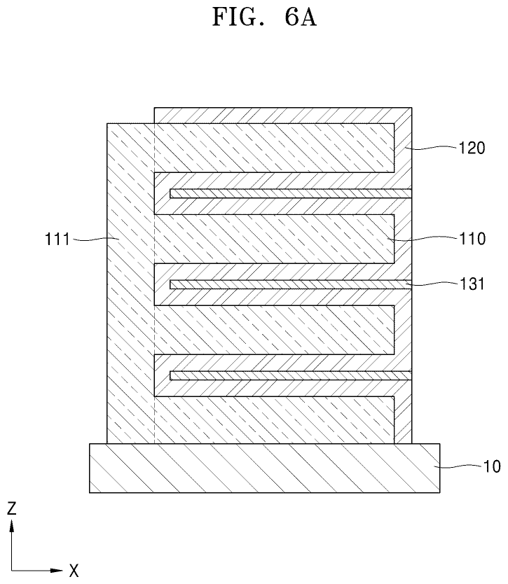

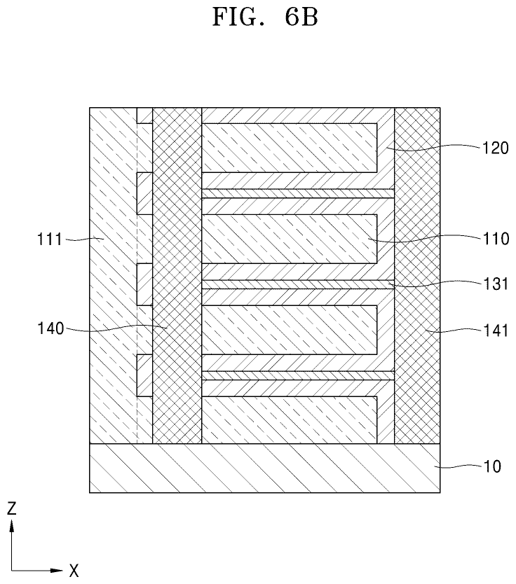

FIGS. 6A and 6B are diagrams describing a portion of a semiconductor device manufacturing method according to an embodiment. The operations of FIGS. 5A to 5G may be performed before the operation of FIG. 6A.

Referring to FIG. 6A, a plurality of channel layers 131 may be formed between the plurality of gate bridges 110. The channel layer 131 may be formed by a CVD process, an MOCVD process, or an ALD process. A gate insulating layer 120 may be formed between the gate bridge 110 and the channel layer 131.

Referring to FIG. 6B, a source electrode 140 arranged apart from the gate via 111 in the first direction (x direction) and a drain electrode 141 arranged apart from the source electrode 140 in the first direction (x direction) may be formed. The source electrode 140 may overlap the plurality of gate bridges 110 in the second direction (z direction). The source electrode 140 may overlap the channel layer 131 in the second direction (z direction).

According to the semiconductor device manufacturing method according to an embodiment, the manufacturing process may be simplified by forming the channel layer in the last operation of the manufacturing process.

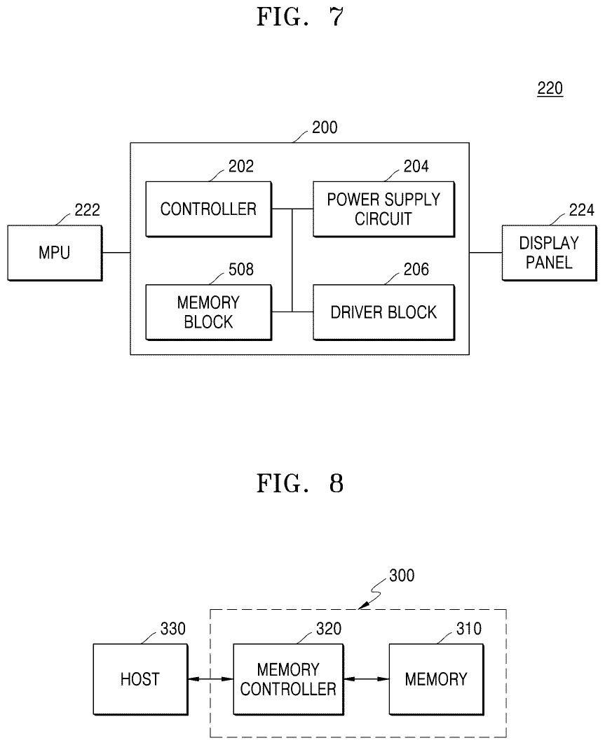

FIG. 7 is a schematic block diagram of a display driver integrated circuit (IC) (DDI) and a display apparatus 220 including the DDI according to an embodiment.

Referring to FIG. 7, a DDI 200 may include a controller 202, a power supply circuit 204, a driver block 206, and a memory block 208. The controller 202 may receive and decode a command applied from a main processing unit (MPU) 222 and control each of the blocks of the DDI 200 to implement an operation according to the command. The power supply circuit 204 may generate a driving voltage in response to the control by the controller 202. The driver block 206 may drive a display panel 224 by using the driving voltage generated by the power supply circuit 204 in response to the control by the controller 202. The display panel 224 may be a liquid crystal display panel or a plasma display panel. The memory block 208 may be a block for temporarily storing commands input to the controller 202 or control signals output from the controller 202 or storing data (e.g., necessary data) and may include a memory such as a RAM and/or a ROM. The power supply circuit 204 and/or the driver block 206 may include at least one of the semiconductor devices 100, 101, and 102 according to the embodiments described above with reference to FIGS. 1 to 4.

FIG. 8 is a block diagram of an electronic system including a semiconductor device according to an embodiment.

An electronic system 300 may include a memory 310 and a memory controller 320. The memory controller 320 may control the memory 310 to read data from the memory 310 and/or write data into the memory 310 in response to a request from a host 330. At least one of the memory 310 and the memory controller 320 may include at least one of the semiconductor devices 100, 101, and 102 according to the embodiments described above with reference to FIGS. 1 to 4.

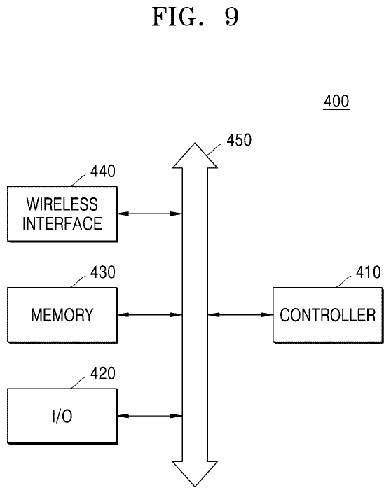

FIG. 9 is a block diagram of an electronic system including a semiconductor device according to an embodiment.

An electronic system 400 may be a wireless communication apparatus or an apparatus capable of transmitting and/or receiving information in a wireless environment. The electronic system 400 may include a controller 410, an input/output (I/O) device 420, a memory 430, and a wireless interface 440, which may be connected to each other through a bus 450.

The controller 410 may include at least one of a microprocessor, a digital signal processor, and any similar processors. The I/O device 420 may include at least one of a keypad, a keyboard, and a display. The memory 430 may be used to store a command executed by the controller 410. For example, the memory 430 may be used to store user data. The electronic system 400 may use the wireless interface 440 to transmit/receive data through a wireless communication network. The wireless interface 440 may include an antenna and/or a wireless transceiver. In some embodiments, the electronic system 400 may be used in the communication interface protocols of third-generation communication systems such as Code Division Multiple Access (CDMA), Global System for Mobile Communications (GSM), North American Digital Cellular (NADC), Extended Time Division Multiple Access (E-TDMA), and/or Wideband Code Division Multiple Access (WCDMA). The electronic system 400 may include at least one of the semiconductor devices 100, 101, and 102 according to the embodiments described above with reference to FIGS. 1 to 4.

According to the semiconductor device and the semiconductor device manufacturing method of the disclosure, a semiconductor device in which a gate bridge overlaps a source electrode to increase and/or maximize a doping effect of the source electrode and reduce and/or minimize a leakage current may be provided, and a semiconductor device manufacturing method with a process simplified by a channel last process may be provided. Although the semiconductor device and the semiconductor device manufacturing method have been described above with reference to the embodiments illustrated in the drawings, the presented embodiments are merely an example and those of ordinary skill in the art will understand that various modifications and other equivalent embodiments may be derived therefrom. Therefore, the presented embodiments should be considered in descriptive sense only and not for purposes of limitation. The scope of the disclosure should be defined not by the foregoing description but by the appended claims, and all differences within the scope equivalent thereto should be construed as being included in the scope of the disclosure.

According to the disclosure, a semiconductor device in which a channel layer and a gate bridge are stacked to increase and/or maximize a current may be provided.

According to the disclosure, a semiconductor device in which a gate bridge is arranged to overlap a source electrode to increase and/or maximize a doping effect of the source electrode and reduce and/or minimize a leakage current may be provided.

According to the disclosure, a semiconductor device manufacturing method with a process simplified by a channel last process may be provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a plurality of gate bridges extending in a first direction and apart from each other in a second direction, the second direction being different from the first direction;
a gate via extending in the second direction and connecting the plurality of gate bridges to each other;
a channel layer between the plurality of gate bridges; and
a source electrode extending in the second direction and apart from the gate via in the first direction,
wherein the plurality of gate bridges to pass through a portion of the source electrode.

2. The semiconductor device of claim 1, further comprising:
a drain electrode extending in the second direction, wherein
the drain electrode is apart from the source electrode in the first direction.

3. The semiconductor device of claim 2, further comprising:
a spacer between the drain electrode and at least one of the plurality of gate bridges.

4. The semiconductor device of claim 1, wherein the channel layer comprises a transition metal dichalcogenide (TMD).

5. The semiconductor device of claim 4, wherein the TMD comprises MoS₂, WSe₂, MoSe₂, or WS₂.

6. The semiconductor device of claim 1, further comprising:
a gate insulating layer surrounding at least one of the plurality of gate bridges.

7. The semiconductor device of claim 6, wherein
at least a portion of the gate insulating layer comprises a portion with a U-shaped cross-section, and
the source electrode fills the portion with the U-shaped cross-section of the gate insulating layer.

8. The semiconductor device of claim 6, wherein the gate insulating layer comprises a high-k material.

9. The semiconductor device of claim 8, wherein the gate insulating layer comprises at least one of aluminum oxide, hafnium oxide, zirconium oxide, or lanthanum oxide.

10. A semiconductor device comprising:
a plurality of gate bridges extending in a first direction and apart from each other in a second direction, the second direction being different from the first direction;
a gate via extending in the second direction and connecting the plurality of gate bridges to each other;
a channel layer between the plurality of gate bridges;
a source electrode extending in the second direction and apart from the gate via in the first direction; and
a drain electrode extending in the second direction and apart from the source electrode in the first direction,
wherein the gate via, the source electrode, and the drain electrode are arranged in the first direction.

11. The semiconductor device of claim 10, wherein at least one of the plurality of gate bridges passes through a portion of the source electrode.

12. The semiconductor device of claim 10, further comprising:
a gate insulating layer surrounding at least one of the plurality of gate bridges.

13. The semiconductor device of claim 10, further comprising:
a spacer between the drain electrode and at least one of the plurality of gate bridges.

14. The semiconductor device of claim 10, wherein the channel layer comprises a transition metal dichalcogenide (TMD).

15. The semiconductor device of claim 14, wherein the TMD comprises MoS₂, WSe₂, MoSe₂, or WS₂.

16. A semiconductor device manufacturing method comprising:
forming a plurality of gate bridges extending in a first direction on a substrate, the plurality of gate bridges being apart from each other in a second direction away from the substrate, the second direction being different from the first direction;
forming a gate via extending in the second direction and connecting the plurality of gate bridges to each other;
forming a gate insulating layer covering the plurality of gate bridges;
forming a source electrode extending in the second direction and apart from the gate via in the first direction; and
forming a channel layer between the plurality of gate bridges,
wherein the plurality of gate bridges pass through a portion of the source electrode.

17. The semiconductor device manufacturing method of claim 16, further comprising:
forming a drain electrode, wherein
the drain electrode extends in the second direction and is apart from the source electrode in the first direction.

18. The semiconductor device manufacturing method of claim 17, further comprising:
forming a spacer between the drain electrode and at least one of the plurality of gate bridges.

19. The semiconductor device manufacturing method of claim 16, wherein the channel layer comprises a transition metal dichalcogenide (TMD).

20. The semiconductor device manufacturing method of claim 19, wherein the TMD comprises MoS₂, WSe₂, MoSe₂, or WS₂.
